(19) United States
(12) Patent Application Publication
(10) Pub. No.: US 2008/0272459 A1
(43) Pub. Date: Nov. 6, 2008

(54) Semiconductor Device and Manufacturing Method of Semiconductor Device

(76) Inventor: JEONG HO PARK, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/112,558

(22) Filed: Apr. 30, 2008

(30) Foreign Application Priority Data
May 4, 2007 (KR) 10-2007-0043483

(51) Int. Cl. H01L 29/92; H01L 21/02

(52) U.S. Cl. 257/532; 438/396; 257/E29.343; 257/E21.008

(57) ABSTRACT

A semiconductor device and method of manufacturing the same are provided. According to certain embodiments, a device layer structure can be formed above a metal wiring line by using a stepped portion of the wiring line as an alignment key. The stepped portion can be provided by a height difference between a first insulating layer and the metal wiring line formed in a trench of the first insulating layer. In one embodiment, the stepped portion can be formed by removing a thickness from a top surface of the first insulating layer after forming the metal wiring line in the trench.

### CROSS-REFERENCE TO RELATED APPLICATION

The present application claims the benefit under 35 U.S.C. § 119 of Korean Patent Application No. 10-2007-0043483, filed May 4, 2007, which is hereby incorporated by reference in its entirety.

### BACKGROUND

During the fabrication process of a semiconductor device, a predetermined layer is typically formed on a wafer, and then a lithography process is performed to provide a desired pattern for the predetermined layer. In general, for the lithography process, a photoresist is coated on the wafer having the predetermined layer, the photoresist is exposed and developed using a mask (reticle), and then the predetermined layer on the wafer is etched using the photoresist pattern as an etch mask. The exposure process of the photoresist tends to determine the accuracy of the semiconductor device manufacturing process.

The layer formation and patterning using the lithography process is repeated throughout the fabrication process of a semiconductor device. During the multiple lithography processes, a position of a pattern formed through a previous process must be aligned with a position of a pattern to be formed in the present process. In detail, only when the mask pattern of the reticle and the wafer are located at the same position as that of the previous pattern forming step can interlayer patterns be precisely and properly aligned. Such an operation for aligning the interlayer patterns will be referred as align work, and a pattern used as a reference of the align work will be referred as an alignment key.

FIG. 1 is a side sectional view illustrating the structure of a semiconductor device having a capacitor device formed on a substrate having a first metal wiring interconnection, and FIG. 2 is a side sectional view illustrating the structure of the semiconductor device after a second metal interconnection is formed on the capacitor device.

Referring to FIG. 1, a second insulating layer 110 is formed on a first insulating layer 100 in which a first metal interconnection 105 is formed. A lower metal layer 120, an insulating layer 130 and an upper metal layer 140 are sequentially formed on a part of the second insulating layer 110 to complete a MIM (metal insulator metal) capacitor.

The MIM capacitor having the lower metal layer 120, the insulating layer 130 and the upper metal layer 140 is formed through a photolithography process. As described above, a photoresist pattern for the first metal interconnection 105 must be aligned with a photoresist pattern for the MIM capacitor in order to precisely and properly align the first metal interconnection 105 with the MIM capacitor.

However, after forming the first metal interconnection 105, the surface of the first insulating layer 100 is planarized through a polishing process such as CMP (chemical mechanical polishing).

Here, it can be difficult to align the MIM capacitor with a lower layer, such as the first metal interconnection 105.

In order to solve such a problem, there has been introduced a scheme for forming a trench type stepped portion 150 in the process of forming the metal layers 120 and 140 of the MIM capacitor, and using the stepped portion 150 as an alignment key.

However, this scheme requires an additionally complicated process, including a photolithography process. In addition, the size of a scribe lane, in which the stepped portion 150 is positioned, is increased. Thus, a substrate area may not be efficiently used.

Furthermore, when a subsequent process is performed, the stepped portion 150 may exert a negative influence upon the planarity of the upper layer.

For example, as illustrated in FIG. 2, to form the second metal interconnection 170 on the MIM capacitor, a third insulating layer 160 is deposited, a plurality of trenches are formed in the third insulating layer 160, and a CMP process is performed.

At this time, the third insulating layer 160 is not uniformly planarized because a region 162 corresponding to the stepped portion 150 is more deeply polished.

Thus, when the trenches are formed with the deeply polished region 162 therebetween, metal material fills in the deeply polished region 162 as well as the trenches, so that short-circuit may occur between the region 162 and the second metal interconnection 170.

### BRIEF SUMMARY

Embodiments of the present invention provide a semiconductor device and a method for manufacturing the same, in which, when a device layer is formed after a metal interconnection process, the device layer can be easily aligned with a lower layer. According to an embodiment, a stepped structure for providing an alignment key can be formed through a simple process. The stepped structure can be created using a metal interconnection formed through the metal interconnection process. In certain embodiments, the alignment key can be provided for forming a MIM capacitor.

A semiconductor device according to an embodiment comprises: a first insulating layer having a trench in a portion of an upper side thereof; a wiring-type metal layer in the trench and having an upper surface higher than the upper surface of the first insulating layer, the height difference between the upper surfaces providing a stepped portion; and a device layer pattern formed on the first insulating layer beside the stepped portion.

A method for manufacturing a semiconductor device according to an embodiment comprises: forming a first insulating layer on a substrate and forming a trench in a part of an upper side of the first insulating layer; forming a wiring-type metal layer in the trench; etching a surface of the first insulating layer such that a stepped portion is formed between the first insulating layer and the metal layer; and forming a device layer pattern on the first insulating layer using the stepped portion as an alignment key.

### BRIEF DESCRIPTION OF THE DRAWINGS

FIG. 1 is a side sectional view illustrating the structure of a semiconductor device having a capacitor device.

FIG. 2 is a side sectional view illustrating the structure of a semiconductor device after a second metal interconnection is formed on the capacitor device of FIG. 1.

FIGS. 3-8 illustrate an alignment method according to an embodiment of the present invention:

FIG. 3 is a side sectional view illustrating the structure of a semiconductor device after a metal layer is formed;

FIG. 4 is a side sectional view illustrating the structure of a semiconductor device after a stepped portion is formed according to an embodiment;

FIG. 5 is a side sectional view illustrating the structure of a semiconductor device after device layers are laminated according to an embodiment;

FIG. 6 is a side sectional view illustrating the structure of a semiconductor device after a first mask pattern is formed on device layers according to an embodiment;

FIG. 7 is a side sectional view illustrating the structure of a semiconductor device after a second mask pattern is formed on device layers according to an embodiment; and

FIG. 8 is a side sectional view illustrating the completed structure of a semiconductor device according to an embodiment.

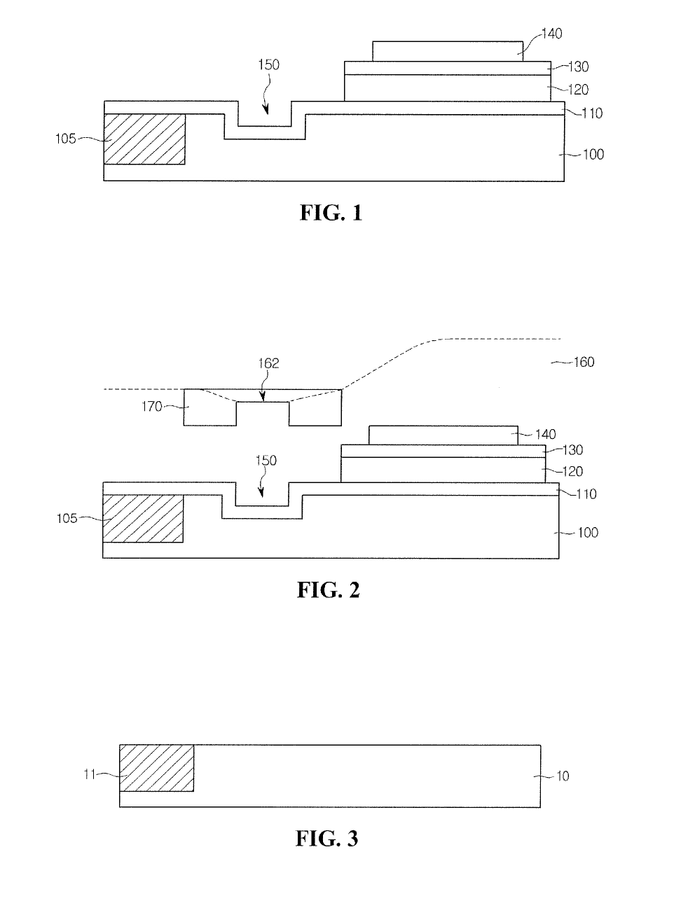

### DETAILED DESCRIPTION

Hereinafter, a semiconductor device and a method for manufacturing the same according to an embodiment will be described in detail with reference to the accompany drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 3 is a side sectional view illustrating the structure of a semiconductor device after a metal layer for a metal wiring is formed.

Referring to FIG. 3, a first insulating layer 10 can be provided on a semiconductor substrate (not shown). A structure such as a lower metal interconnection (not shown) can be provided below the first insulating layer 10 on the semiconductor substrate. In one embodiment to form the wiring-type metal layer 11, a photoresist can be coated on the first insulating layer 10.

Next, the photoresist is selectively patterned through an exposure and development process to define a trench area.

Then, the first insulating layer 10 is selectively removed using the patterned photoresist as a mask to form a trench.

After removing the photoresist, a metal layer is formed on the first insulating layer 10 such that the metal layer fills the trench. The metal layer can include a conductive material such as copper.

Then, the metal layer on the first insulating layer 10 and not in the trench can be removed through a polishing process such as a CMP process to complete the wiring-type metal layer 11 as illustrated in FIG. 3.

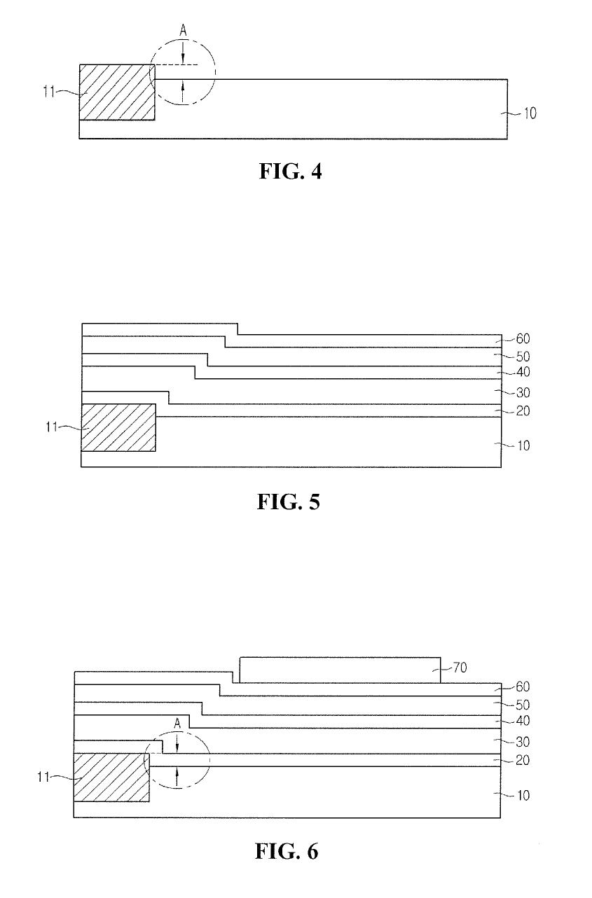

Referring to FIG. 4, after completing the metal layer 11, a wet etching process can be performed to etch the surface of the first insulating layer 10 by a predetermined thickness. The wet etching process can be performed using, for example, an oxide layer etching solution.

Since the metal layer 11 and the first insulating layer 10 are etched at different etching rates, a stepped portion A is formed between the metal layer 11 and the first insulating layer 10 as illustrated in FIG. 4. The stepped portion A can be used as an alignment key for the subsequent process.

According to certain embodiments, the wet etching conditions can be adjusted such that the stepped portion A has a height of between about 500 Å and about 2500 Å.

For example, in a certain embodiment, if the stepped portion A has a height less than 500 Å, the stepped portion A may be difficult to use as the alignment key. If the stepped portion A has a height greater than 2500 Å, profiles of layers formed through the subsequent process may be difficult to precisely control.

Referring to FIG. 5, after forming the stepped portion A, a second insulating layer 20 can be formed on the first insulating layer 10 and the metal layer 11. In one embodiment, the second insulating layer 20 can be formed by growing material such as SiC. In another embodiment, the second insulating layer 20 can include a nitride layer.

Then, device layers can be formed on the second insulating layer 20 by using the stepped portion A as the alignment key. According to an embodiment, the device layers can be a lower metal layer 30, a first insulating film 40, an upper metal layer 50 and a second insulating film 60 used to form a MIM structure.

According to one process, the lower metal layer 30 can be formed on the second insulating layer 20, and the first insulating film 40 can be formed on the lower metal layer 30.

Next, the upper metal layer 50 can be formed on the first insulating film 40. The upper metal layer 50 and the lower metal layer 30 can have material structures including, but not limited to Ti, Ti/TiN and Ti/Al/TiN.

Then, the second insulating film 60 can be formed on the upper metal layer 50. In one embodiment, the first and second insulating films 40 and 60 can be prepared in the form of a nitride film.

After performing the lamination process for the lower metal layer 30, the first insulating film 40, the upper metal layer 50 and the second insulating film 60 as described above, an etching process can be performed to form a capacitor structure.

Referring to FIG. 6, a photoresist can be coated on the second insulating film 60 and selectively patterned through an exposure and development process, so that the first mask pattern 70 is formed.

A reticle used for the exposure and development process is aligned based on the stepped portion A, so that the first mask pattern 70 can be precisely aligned with a lower structure of the substrate.

The first mask pattern 70 can be used to form the MIM capacitor.

According to an embodiment of the present invention, stepped portions formed when the second insulating layer 20, the lower metal layer 30, the first insulating film 40, the upper metal layer 50 and the second insulating film 60 are deposited are not related to the alignment key. Instead, the stepped portion A between the metal layer 11 and the first insulating layer 10 can be used as the alignment key by using an optical measurement apparatus such as an SEM (scanning electric microscope).

In operation, the SEM irradiates an electronic beam onto a wafer having a stepped portion, and detects secondary electrons reflected from the wafer to generate electric signals based on the secondary electrons. Then, the SEM performs scan synchronization to obtain an SEM image, and identifies the stepped portion on the SEM image to use the stepped portion as the alignment key.

After the first mask pattern 70 is aligned and formed, the etching process can be performed using the first mask pattern 70 to remove the lower metal layer 30, the first insulating film 40, the upper metal layer 50 and the second insulating film 60 from an area on which the first mask pattern 70 is not formed.

Then, the first mask pattern 70 is removed.

The above described etching process using the first mask pattern 70 can be used for forming a lower metal part of the capacitor structure.

In a further embodiment, an etching process for forming an upper metal part of the capacitor structure is then performed.

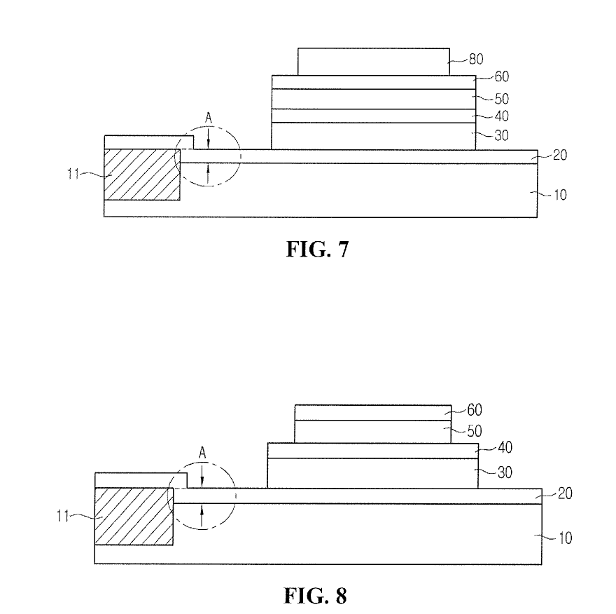

Referring to FIG. 7, a photoresist can be coated on the wafer and selectively patterned through exposure and development processes to form the second mask pattern 80 on the second insulating film 60.

The upper metal layer 50 and the second insulating film 60 can be formed to have an area narrower than that of the lower metal layer 30 and the first insulating film 40 by forming the second mask pattern 80 with a size smaller than that of the first mask pattern 70.

According to an embodiment, a reticle for forming the second mask pattern 80 can be aligned based on the stepped portion A, so that the second mask pattern 80 can be aligned with the device layers of the lower metal part and the lower structure of the substrate.

Then, an etching process can be performed using the second mask pattern 80 to remove a part of the upper metal layer 50 and the second insulating film 60 on which the second mask pattern 80 is not formed.

Referring to FIG. 8, the second mask pattern 80 can be removed.

According to embodiments as described above, the first insulating layer 10 can be wet-etched to form the stepped portion A between the first insulating layer 10 and the metal layer 11. Then, this stepped portion A can be used as the alignment key, so that a conventional complicated process is not required.

In detail, an additional layer step for forming the alignment key is not required. Instead, an alignment structure can be formed in the process of forming an existing layer step. According to an embodiment, the alignment structure can be formed in the process of forming the interlayer dielectric layer, the metal interconnection, and the device layer structure, so that the manufacturing process can be minimized and the production yield can be improved.

Further, according to an embodiment, a subsequent process of, for example, forming a second interconnection can be performed after the MIM capacitor process without exerting an influence upon an upper layer, such as an interlayer dielectric layer in which the second interconnection is formed. Accordingly, the reliability of the semiconductor device can be improved and the defect rate of the semiconductor device can be reduced.

Accordingly, embodiments of the present invention can reduce or eliminate scribe lane regions by effectively using substrate area structures as an alignment key.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a first insulating layer having a trench;
a wiring-type metal layer formed in the trench and having an upper surface higher than an upper surface of the first insulating layer, wherein the height difference between the upper surface of the wiring-type metal layer and the upper surface of the first insulating layer provides a stepped portion; and
a device layer pattern on the first insulating layer in a region adjacent the stepped portion.

2. The semiconductor device according to claim 1, wherein the stepped portion has a height of between about 500 Å and about 2500 Å.

3. The semiconductor device according to claim 1, further comprising a second insulating layer on the first insulating layer, wherein the second insulating layer is below the device layer pattern.

4. The semiconductor device according to claim 3, wherein the second insulating layer comprises SiC.

5. The semiconductor device according to claim 3, wherein the second insulating layer comprises a nitride layer.

6. The semiconductor device according to claim 1, wherein the device layer pattern comprises a MIM (metal insulator metal) structure, wherein the MIM structure comprises:
a lower metal layer on the first insulating layer in the region adjacent the stepped portion;
a first insulating film on the lower metal layer;
an upper metal layer on the first insulating film; and
a second insulating film on the upper metal layer.

7. The semiconductor device according to claim 6, wherein at least one of the upper and lower metal layers comprises at least one metal layer structure selected from the group consisting of Ti, Ti/TiN and Ti/Al/TiN.

8. The semiconductor device according to claim 6, wherein at least one of the first and second insulating films comprises a nitride layer.

9. The semiconductor device according to claim 6, wherein the second insulating film and the upper metal layer have widths narrower than widths of the first insulating film and the lower metal layer.

10. The semiconductor device according to claim 9, wherein the second insulating film has a width equal to a width of the upper metal layer, and the first insulating film has a width equal to a width of the lower metal layer.

11. A method for manufacturing a semiconductor device, comprising:
forming a first insulating layer on a substrate and forming a trench in a portion of the first insulating layer;
forming a wiring-type metal layer in the trench;
etching a top surface of the first insulating layer such that a stepped portion is formed between the first insulating layer and the metal layer; and
forming a device layer pattern on the first insulating layer using the stepped portion as an alignment key.

12. The method according to claim 11, further comprising forming a second insulating layer on the first insulating layer before forming the device layer pattern on the first insulating layer.

13. The method according to claim 11, wherein forming the device layer pattern on the first insulating layer comprises:
forming a lower metal layer on the first insulating layer;
forming a first insulating film on the lower metal layer;
forming an upper metal layer on the first insulating film;
forming a second insulating film on the upper metal layer;
forming a first mask pattern using the stepped portion as the alignment key; and
etching the second insulating film, the upper metal layer, the first insulating film and the lower metal layer using the first mask pattern as an etch mask.

14. The method according to claim 13, wherein forming the device layer pattern on the first insulating layer further comprises:
removing the first mask pattern;
forming a second mask pattern on the remaining second insulating film;
etching the second insulating film and the upper metal layer using the second mask pattern as an etch mask; and
removing the second mask pattern.

15. The method according to claim 14, wherein the second mask pattern is formed using the stepped portion as the alignment key.

16. The method according to claim 14, wherein the second mask pattern has a width narrower than a width of the first mask pattern.

17. The method according to claim 16, wherein the second mask pattern is aligned at a center portion of the first mask pattern.

18. The method according to claim 11, wherein forming the wiring-type metal layer in the trench comprises:
forming a metal layer on the first insulating layer including filling the trench; and
planarizing the metal layer such that the top surface of the first insulating layer is exposed.

19. The method according to claim 11, wherein etching the top surface of the first insulating layer comprises performing a wet etching process.

20. The method according to claim 11, wherein etching the top surface of the first insulating layer comprises using an oxide layer etching solution.
